(19) United States
(12) Patent Application Publication
(10) Pub. No.: US 2016/0141148 A1
(43) Pub. Date: May 19, 2016

(54) PLASMA PROCESS APPARATUS HAVING VIEW PORT

(71) Applicants: Jongwoo SUN, Seoul (KR); Kyeong-Seok JEONG, Hwaseong-si (KR); Jihee KIM, Goyang-si (KR)

(72) Inventors: Jongwoo SUN, Seoul (KR); Kyeong-Seok JEONG, Hwaseong-si (KR); Jihee KIM, Goyang-si (KR)

(21) Appl. No.: 14/790,288

(22) Filed: Jul. 2, 2015

(30) Foreign Application Priority Data
Nov. 17, 2014 (KR) 10-2014-0160035

(51) Int. Cl. H01J 37/32

(52) U.S. Cl. CPC H01J 37/32009

(57) ABSTRACT

A plasma process apparatus includes a process chamber including a view port, a window plate disposed in the view port of the process chamber, and a light guide disposed on a surface of the window plate facing toward an interior of the process chamber, the light guide including openings extending in one direction in parallel to each other.

### CROSS-REFERENCE TO RELATED APPLICATION

Korean Patent Application No. 10-2014-0160035, filed on Nov. 17, 2014, in the Korean Intellectual Property Office, and entitled: “Plasma Process Apparatus Having View Port” is incorporated by reference herein its entirety.

### BACKGROUND

1. Field

Embodiments relate to a plasma process apparatus having a view port that transmits light generated by plasma.

2. Description of the Related Art

A plasma process apparatus, e.g., plasma etching equipment, may monitor a state of plasma and an ongoing state of process using plasma by analyzing light generated by the plasma. The plasma process apparatus may include an analysis unit to analyze the light generated by plasma while a designed process using plasma is performed.

### SUMMARY

In accordance with an aspect of embodiments, a plasma process apparatus includes a process chamber having a view port, a window plate disposed in the view port of the process chamber, and a light guide disposed on a surface of the window plate facing toward an interior of the process chamber, the light guide including openings extending in one direction in parallel to each other.

In an embodiment, the apparatus may further include a guide coating layer located on a surface of the light guide toward the inside of the process chamber.

In another embodiment, the guide coating layer may include yttria (Y₂O₃).

In still another embodiment, the guide coating layer may extend along inner walls of the openings.

In yet another embodiment, the apparatus may further include a sealing element located between the window plate and the light guide. The sealing element may surround the openings.

In yet another embodiment, the light guide may further include a flange groove accommodating the sealing element.

In accordance with another aspect of embodiments, a plasma process apparatus includes a process chamber having a process chuck which supports a process object and a view port through which light by plasma passes, a light transmission element located in the view port of the process chamber, and an analysis unit which analyzes light applied through the light transmission element. The light transmission element includes a light guide including guide ribs extending in one direction and a window plate located on surfaces of the guide ribs toward the analysis unit.

In an embodiment, the guide ribs may extend in a direction parallel with a surface of the process chuck.

In another embodiment, the light guide may further include a guide coating layer covering end portions of the guide ribs toward an inside of the process chamber.

In still another embodiment, the light guide may further include a guide oxidized layer formed on a surface thereof. The guide coating layer may be located on the guide oxidized layer.

In yet another embodiment, a width of each the guide ribs may be constant.

In yet another embodiment, a distance between adjacent guide ribs may be greater than a width of each guide rib.

In yet another embodiment, the light guide may further include a guide flange located on outsides of the guide ribs. A distance between the window plate and the guide flange may be greater than a distance between the guide ribs and the window plate.

In yet another embodiment, the guide ribs may be in directly contact with the window plate.

In yet another embodiment, the analysis unit may include an optic emission spectrometer (OES).

In accordance with still another aspect of embodiments, a plasma process apparatus includes a process chamber having a view port, a light guide located in the view port of the process chamber, and including a guide body having a plurality of slits and a guide flange located on an outside of the guide body, a window plate located on a surface of the guide body toward an outside of the process chamber, and an analysis unit configured to analyzes light applied through the plurality of slits and the window plate.

In an embodiment, opposite surfaces of the guide flange may be located between opposite surfaces of the guide body.

In another embodiment, the light guide may further include a guide coating layer located on the surface of the guide body which protrudes from the guide flange in a direction toward an inside of the process chamber.

In still another embodiment, the apparatus may further include a cover plate located between the window plate and the light guide. Plasma resistance of the cover plate may be greater than plasma resistance of the window plate.

In yet another embodiment, a thickness of the cover plate may be smaller than a thickness of the window plate.

In accordance with yet another aspect of embodiments, a plasma process apparatus includes a process chamber including a view port, a window plate in the view port of the process chamber, and a light guide between the window plate and an interior of the process chamber, the light guide including slits in light communication with the interior of the process chamber and with the window plate.

In an embodiment, the light guide may include ribs spaced apart from each other along a first direction, spaces between the ribs defining the slits, and a thickness of each rib along the first direction being smaller than a width of each space along the first direction.

In another embodiment, the light guide may be in the view port, transmittance of light to the window plate being only through the slits of the light guide.

In still another embodiment, the light guide may extend from the window plate to an interior of the process chamber within a sidewall of the process chamber.

In yet another embodiment, the slits may be perpendicular to the window plate.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic view of a plasma process apparatus in accordance with an embodiment;

FIG. 2 illustrates a view of a light transmission element of a plasma process apparatus in accordance with an embodiment;

FIGS. 3 and 4 illustrate views of a light guide of a plasma process apparatus in accordance with an embodiment;

FIG. 5 illustrates a front view of a light guide of a plasma process apparatus in accordance with another embodiment;

FIG. 6 illustrates a front view of a light guide of a plasma process apparatus in accordance with still another embodiment;

FIG. 7 illustrates a cross-sectional view of a light guide of a plasma process apparatus in accordance with another embodiment;

FIG. 8 illustrates a cross-sectional view of a light transmission element of a plasma process apparatus in accordance with another embodiment; and

FIG. 9 illustrates a view of a light transmission element of a plasma process apparatus in accordance with still another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms “first,” “second,” “third,” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the embodiments.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising.” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

In addition, unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

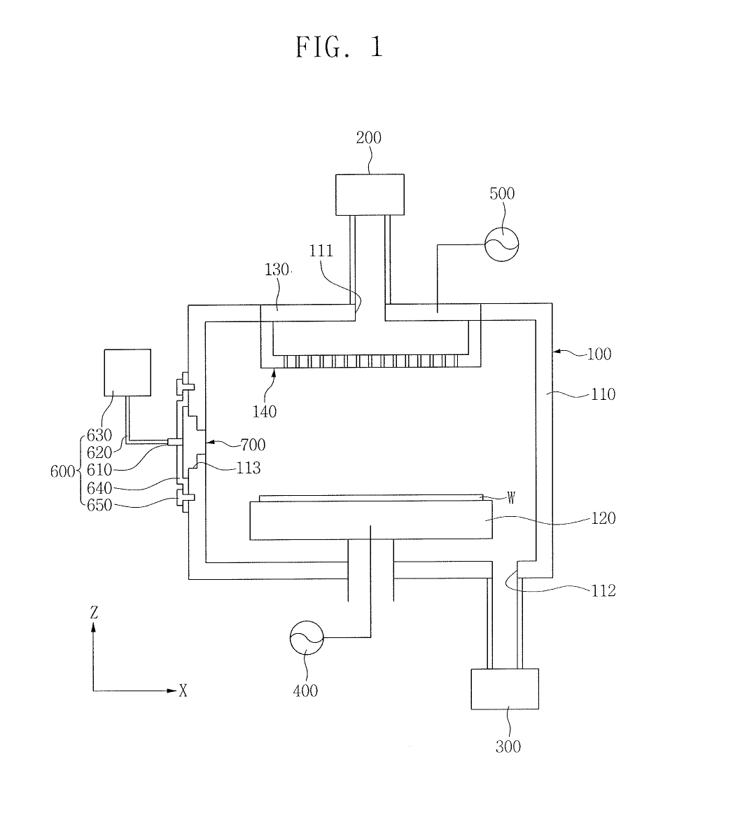

FIG. 1 is a schematic view of a plasma process apparatus in accordance with an embodiment.

Referring to FIG. 1, a plasma process apparatus in accordance with an embodiment may include a process chamber 100, a gas supply 200, a vacuum pump 300, a first power supply 400, a second power supply 500, an analysis unit 600, and a light transmission element 700.

The process chamber 100 may provide a space in which a process object W is manufactured using plasma. The process object W may include a wafer. The process chamber 100 may include a chamber body 110, a process chuck 120, an upper electrode 130, and a showerhead 140.

The chamber body 110 may surround a space in which a designed process using plasma is performed. For example, the process of manufacturing the process object W using plasma may be performed inside, e.g., in an interior space defined by walls of, the chamber body 110. The chamber body 110 may include an inlet 111, an outlet 112, and a view port 113.

The inlet 111 may be connected to the gas supply 200. The gas supply 200 may supply reaction gas to the inside of the chamber body 110 through the inlet 111. For example, the inlet 111 may be located in an upper surface of the chamber body 110. The outlet 112 may be connected to the vacuum pump 300. The reaction gas remaining inside of the chamber body 110 and process by-products generated by plasma may be discharged to an outside of the chamber body 110 through the outlet 112. For example, the outlet 112 may be located in a lower surface of the chamber body 110. Light generated by plasma generated inside the chamber body 110 may be emitted to the outside by penetrating the view port 113. The view port 113 may be located in a side wall of the chamber body 110. For example, as illustrated in FIG. 1, the view port 113 may be an opening through an entire side wall of the chamber body 110, and may have first and second areas with different heights along the Z-axis, e.g., the first area closer to an interior of the chamber body 110 may have a lower height than the second area closer to an exterior of the chamber body 110.

The process chuck 120 may support the process object W while the designed process using plasma is performed. The process chuck 120 may be located inside the chamber body 110. The process chuck 120 may be located to face the inlet 111 of the chamber body 110. For example, the process chuck 120 may be located above the lower surface of the chamber body 110.

The process chuck 120 may be electrically connected to the first power supply 400. For example, the process chuck 120 may include an electrostatic chuck (ESC).

The upper electrode 130 may be electrically connected to the second power supply 500. For example, plasma may be generated inside the chamber body 110 due to a voltage difference between the process chuck 120 and the upper electrode 130.

The upper electrode 130 may be located to face the process chuck 120. For example, the upper electrode 130 may be located on the upper surface of the chamber body 110. The upper electrode 130 may be located adjacent to the inlet 111 of the chamber body 110. For example, the inlet 111 of the chamber body 110 may pass through the upper electrode 130.

The showerhead 140 may spray the reaction gas supplied from the gas supply 200 into the inside of the chamber body 110. The showerhead 140 may be located to face the process chuck 120. The showerhead 140 may be located on the upper surface of the chamber body 110. For example, the showerhead 140 may be located under the inlet 111 of the chamber body 110. The showerhead 140 may be located under the upper electrode 130. For example, the showerhead 140 may be electrically connected to the upper electrode 130.

The analysis unit 600 may monitor a change of a state of plasma generated inside the process chamber 100. The analysis unit 600 may monitor the state of plasma using the light penetrating through the view port 113 of the process chamber 100. The analysis unit 600 may be located outside the process chamber 100. The analysis unit 600 may include an optical probe 610, an optical cable 620, and a plasma analysis unit 630.

The optical probe 610 may be located near the view port 113 of the process chamber 100. The optical cable 620 may optically connect the optical probe 610 to the plasma analysis unit 630. The plasma analysis unit 630 may analyze the light transferred by the optical probe 610 and the optical cable 620. For example, the plasma analysis unit 630 may include an optic emission spectrometer (OES).

The analysis unit 600 may further include a probe fixing cover 640 and a cover coupling element 650. The probe fixing cover 640 may surround the optical probe 610. The cover coupling element 650 may couple the probe fixing cover 640 to the process chamber 100. A location of the optical probe 610 may be fixed by the probe fixing cover 640 and the cover coupling element 650.

The light transmission element 700 may be located in the view port 113 of the process chamber 100. The light generated by plasma inside the chamber body 110 may penetrate, e.g., be transmitted, through the light transmission element 700 to be incident on the optical probe 610 of the analysis unit 600. The plasma analysis unit 630 of the analysis unit 600 may analyze the light penetrating the light transmission element 700, i.e., the light incident on the optical probe 610.

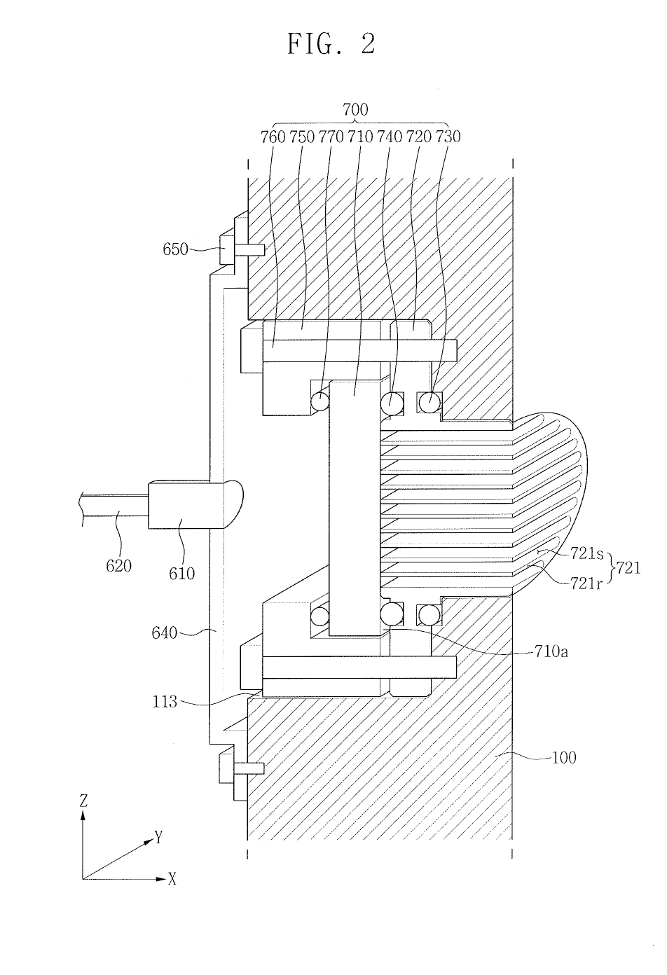

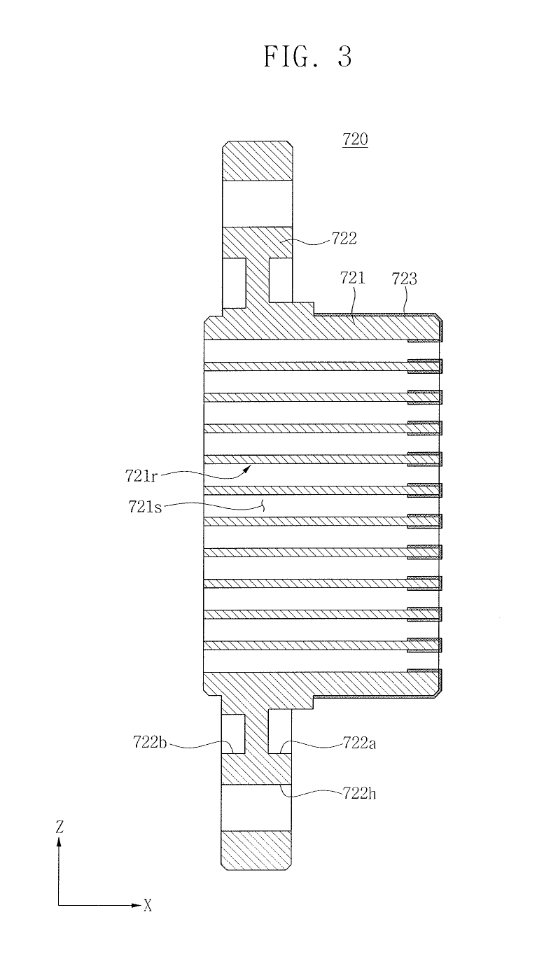

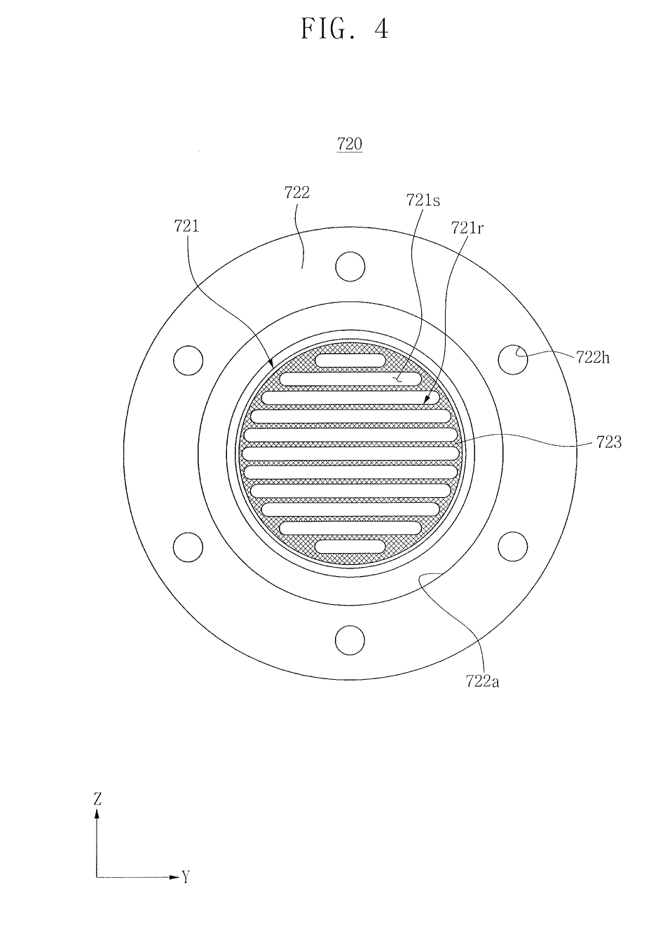

FIG. 2 is an enlarged view through a side wall of the chamber body 110 showing the light transmission element 700 of a plasma process apparatus in accordance with an embodiment. FIG. 3 is a cross-sectional view showing a light guide of the light transmission element 700 shown in FIG. 2. FIG. 4 is a front view showing the light guide of the light transmission element 700 shown in FIG. 2, which is viewed from an inside of the process chamber 100.

Referring to FIGS. 2 to 4, the light transmission element 700 of the plasma process apparatus in accordance with the embodiment may include a window plate 710, a light guide 720, an inner sealing element 730, and an outer sealing element 740.

Plasma generated inside the chamber body 110 may be emitted to the outside through the window plate 710. The window plate 710 may include a high transmittance material. For example, the window plate 710 may include quartz.

The light guide 720 may prevent a progressive clogging of the window plate 710. For example, process by-products generated by plasma inside the chamber body 110 and progressing toward the window plate 710 may be blocked by the light guide 720. For example, the process by-products generated by the designed process using plasma may be deposited on a surface of the light guide 720 facing toward an inside, e.g., interior, of the process chamber 100.

In detail, the light guide 720 may be located on a surface 710a of the window plate 710 facing toward the inside of the process chamber 100, e.g., the light guide 720 may be located between the window plate 710 and the interior of the process chamber 100. As illustrated in FIG. 3, the light guide 720 may include a guide body 721, a guide flange 722, and a guide coating layer 723.

The guide body 721 may partially cover the surface 710a of the window plate 710. That is, as illustrated in FIG. 2, the surface 710a of the window plate 710 facing toward the inside of the process chamber 100 may be partially exposed by the guide body 721.

The guide body 721 may be located on the surface 710a of the window plate 710. For example, the guide body 721 may be in direct contact with the surface 710a of the window plate 710.

The guide body 721 may include a material having a physical rigidity greater than the window plate 710. For example, the guide body 721 may include aluminum.

The guide body 721 may include openings 721s. The openings 721s may perforate the guide body 721, e.g., the openings 721s may extend through the entire length of the guide body 721 along the X-axis direction to provide light communication between the interior of the process chamber 100 and the window plate 710. The openings 721s may expose the surface 710a of the window plate 710 in a direction toward the inside of the process chamber 100.

The openings 721s may extend in one direction. For example, each opening 721s may be formed to have a slit shape. The openings 721s may extend in parallel to each other. For example, the openings 721s may extend in a Y-axis direction when viewed from the interior of the process chamber 100 (FIG. 4). Here, the Y-axis direction may be a direction which crosses the view port 113 of the process chamber 100 in parallel to a surface of the process chuck 120 shown in FIG. 1.

The guide body 721 may include guide ribs 721r. The guide ribs 721r may be located between the openings 721s. The guide ribs 721r may cross the surface of the window plate 710. The surface 710a of the window plate 710 facing toward the inside of the process chamber 100 may be covered by the guide ribs 721r, e.g., the surface 710a of the window plate 710 may be covered by alternating guide ribs 721r and openings 721s (FIG. 2).

The guide ribs 721r may be defined by the openings 721s. The guide ribs 721r may extend in one direction. The guide ribs 721r may extend in the same direction as the openings 721s. For example, the guide ribs 721r may extend in the Y-axis direction. The guide ribs 721r may extend in parallel to each other.

Surfaces of the guide ribs 721r toward the window plate 710 may be vertically aligned with a surface of the guide body 721. For example, the guide ribs 721r may be in direct contact with the window plate 710. The surfaces of the guide ribs 721r facing toward the inside of the process chamber 100 may be vertically aligned with the surface of the guide body 721 heading toward the inside of the process chamber 100.

In the plasma process apparatus in accordance with the embodiment, light generated by plasma may propagate toward the window plate 710 through the openings 721s of the light guide 720, which are disposed in parallel to each other and formed to have a slit shape. That is, in the plasma process apparatus in accordance with the embodiment, the light guide 720 may include the guide ribs 721r which extend in one direction in parallel. Therefore, in the plasma process apparatus in accordance with the embodiment, a region covering the surface 710a of the window plate 710 to maintain structural stability of the guide body 721 may be minimized.

The guide ribs 721r may have a constant width. For example, a width of each opening 721s may be greater than a width of each guide rib 721r. e.g., along the Z-axis direction. A distance between adjacent guide ribs 721r, e.g., along the Z-axis direction, may be greater than the width, e.g., thickness, of each guide rib 721r.

The guide flange 722 may be coupled to the process chamber 100. The light guide 720 may be coupled to the process chamber 100 by the guide flange 722. A location of the guide body 721 may be fixed by the guide flange 722.

The guide flange 722 may be located outside the guide body 721. As illustrated in FIG. 4, the guide flange 722 may surround the openings 721s, and the guide flange 722 may surround the guide ribs 721r.

For example, as illustrated in FIG. 2-3, the guide flange 722 may be formed to protrude from the guide body 721. The guide flange 722 may have a region which extends from the guide body 721. The guide flange 722 may include the same material as the guide body 721. For example, the guide flange 722 may include aluminum. For example, the guide flange 722 and the guide body 721 may be integrated into one body.

A thickness of the guide flange 722 may be smaller than a thickness of the guide body 721 along the X-axis direction. In detail, a surface of the guide flange 722 facing toward the window plate 710 may be located closer to the interior of the process chamber 100, e.g., along the X-axis, than the surface of the guide body 721 facing toward the window plate 710. The guide flange 722 may be spaced apart from the window plate 710. The surface of the guide flange 722 facing toward the process chamber 100 may be located closer to the window plate 710, e.g., along the X-axis, than the surface of the guide body 721 facing toward the process chamber 100. The opposite surfaces of the guide flange 722, which are spaced apart from each other along the X-axis, may be located between the opposite surfaces of the guide body 721, which are spaced apart from each other along the X-axis.

The surface of the guide flange 722 facing toward the inside of the process chamber 100 may face a side wall of the process chamber 100. For example, a distance between a side surface of the guide body 721 which protrudes from the guide flange 722 in a direction facing toward the inside of the process chamber 100 and the process chamber 100 may be the same as a distance between a side surface of the guide flange 722 and the process chamber 100. For example, the view port 113 of the process chamber 100 may have different sized areas, and the relatively small sized area of the view port 113 may be located close to the inside of the process chamber 100.

The guide coating layer 723 may prevent damage to the light guide 720 due to plasma generated inside the process chamber 100. For example, the light guide 720 may not be etched by the guide coating layer 723 while an etching process of the process object W is performed using plasma.

The guide coating layer 723 may be located on the surface of the light guide 720 facing toward the inside of the process chamber 100. The surface of the light guide 720 facing toward the inside of the process chamber 100 may be covered by the guide coating layer 723. The guide coating layer 723 may expose the surface of the guide flange 722 toward the inside of the process chamber 100. For example, the guide coating layer 723 may be located on the surface of the guide body 721 protruding from the guide flange 722 in the direction toward the inside of the process chamber 100.

The guide coating layer 723 may, e.g., partially, extend along inner walls of the openings 721s. For example, the guide coating layer 723 may surround, e.g., only, end portions of the guide ribs 721r facing toward the inside of the process chamber 100.

The guide coating layer 723 may include a material having low reactivity with plasma. Plasma resistance of the guide coating layer 723 may be greater than plasma resistance of the guide body 721. For example, the guide coating layer 723 may include yttria (Y₂O₃).

The inner sealing element 730 may prevent diffusing/progressing of plasma generated inside the process chamber 100 along the surface of the light guide 720. The inner sealing element 730 may be located between the light guide 720 and the process chamber 100. For example, the inner sealing element 730 may be located on the surface of the guide flange 722 toward the inside of the process chamber 100.

The inner sealing element 730 may extend along a side surface of the guide body 721, i.e., inside an inner flange groove 722a (FIG. 4). The inner sealing element 730 may surround the openings 721s. The inner sealing element 730 may surround the guide ribs 721r. For example, the inner sealing element 730 may include an O-ring.

The guide flange 722 may include the inner flange groove 722a accommodating the inner sealing element 730. A location of the inner sealing element 730 may be fixed by the inner flange groove 722a of the guide flange 722.

The outer sealing element 740 may be located between the window plate 710 and the light guide 720. For example, the outer sealing element 740 may be located on the surface of the guide flange 722 facing the window plate 710. The outer sealing element 740 may be located on an edge of the window plate 710.

The outer sealing element 740 may extend along a side surface of the guide body 721. The outer sealing element 740 may extend along the edge of the window plate 710. The outer sealing element 740 may surround the openings 721s. The outer sealing element 740 may surround the guide ribs 721r. The outer sealing element 740 may include the same material as the inner sealing element 730. For example, the outer sealing element 740 may include an O-ring.

The guide flange 722 may further include an outer flange groove 722b accommodating the outer sealing element 740. A location of the outer sealing element 740 may be fixed by the outer flange groove 722b of the guide flange 722.

The outer flange groove 722b may be symmetrical to the inner flange groove 722a based on the guide flange 722. The outer sealing element 740 may have a different size from the inner sealing element 730. A size of the outer flange groove 722b may be different from a size of the inner flange groove 722a. A depth of the outer flange groove 722b may be different from a depth of the inner flange groove 722a.

The light transmission element 700 may further include a window fixing frame 750, a frame coupling element 760, and a buffer element 770.

The window fixing frame 750 may fix a location of the window plate 710. The window fixing frame 750 may surround a side surface of the window plate 710. An edge of the surface of the window plate 710 toward the outside of the process chamber 100 may be covered by the window fixing frame 750.

The frame coupling element 760 may couple the window fixing frame 750 to the process chamber 100. The frame coupling element 760 may be located outside the window plate 710. The frame coupling element 760 may pass through the window fixing frame 750.

The frame coupling element 760 may couple the light guide 720 to the process chamber 100. For example, the frame coupling element 760 may pass through the light guide 720. The frame coupling element 760 may be located outside the inner sealing element 730 and the outer sealing element 740.

The guide flange 722 may include a flange coupling hole 722h in which the frame coupling element 760 is inserted. The flange coupling hole 722h may perforate the guide flange 722. The flange coupling hole 722h may be located outside the inner flange groove 722a and the outer flange groove 722b.

The buffer element 770 may prevent damage to the window plate 710 by the window fixing frame 750. The buffer element 770 may be located on the surface of the window plate 710 toward the outside of the process chamber 100. The buffer element 770 may extend along the edge of the window plate 710. For example, the buffer element 770 may include an O-ring.

In the plasma process apparatus in accordance with the embodiment, the light transmission element 700 located in the view port 113 of the process chamber 100 may include the light guide 720 located on the surface of the window plate 710 facing toward the inside of the process chamber 100 and including the openings 721s. Thus, in the plasma process apparatus in accordance with the embodiment, a progressive clogging of the window plate 710 may be prevented, as particles may be deposited on surfaces of the guide ribs 721r of the light guide 720 before reaching the window plate 710. Further, in the plasma process apparatus in accordance with the embodiment, the openings 721s of the light guide 720 may be formed to have a slit shape which extends in one direction in parallel. Thus, in the plasma process apparatus in accordance with the embodiment, an amount of light which penetrates though the openings 721s of the light guide 720 and the window plate 710 to reach the analysis unit 600 may be maximized, as the slit shape of the openings 721s prevents or substantially minimizes penetration of particles therethrough. Therefore, in the plasma process apparatus in accordance with the embodiment, the progressive clogging of the window plate 710 may be prevented and light applied to the analysis unit 600 penetrating the light transmission element 700 may be sufficiently ensured from a beginning of a designed process. As a result, in the plasma process apparatus in accordance with the embodiment, a state of plasma generated inside the process chamber 100 and an ongoing state of the designed process using plasma may be accurately monitored.

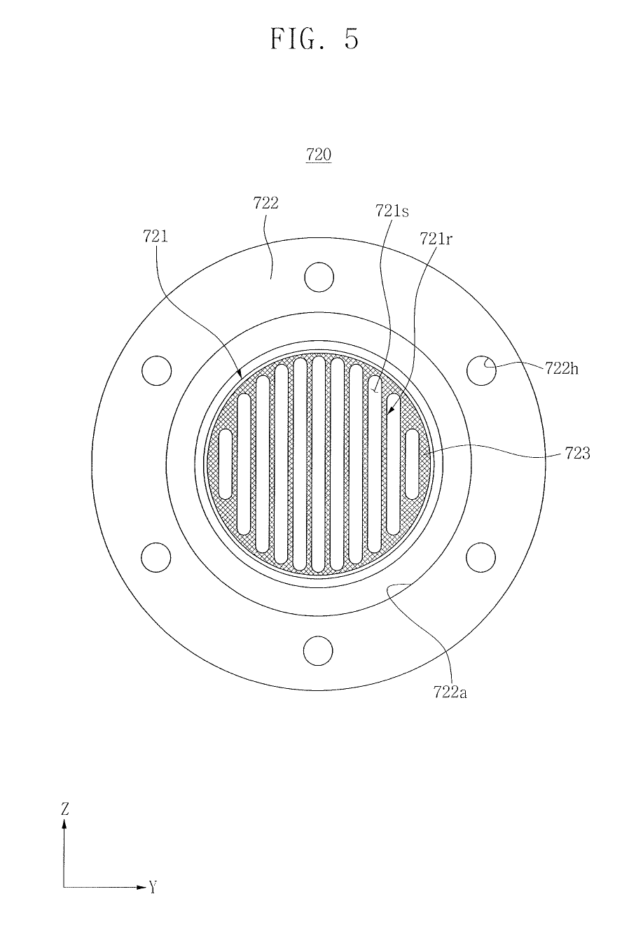

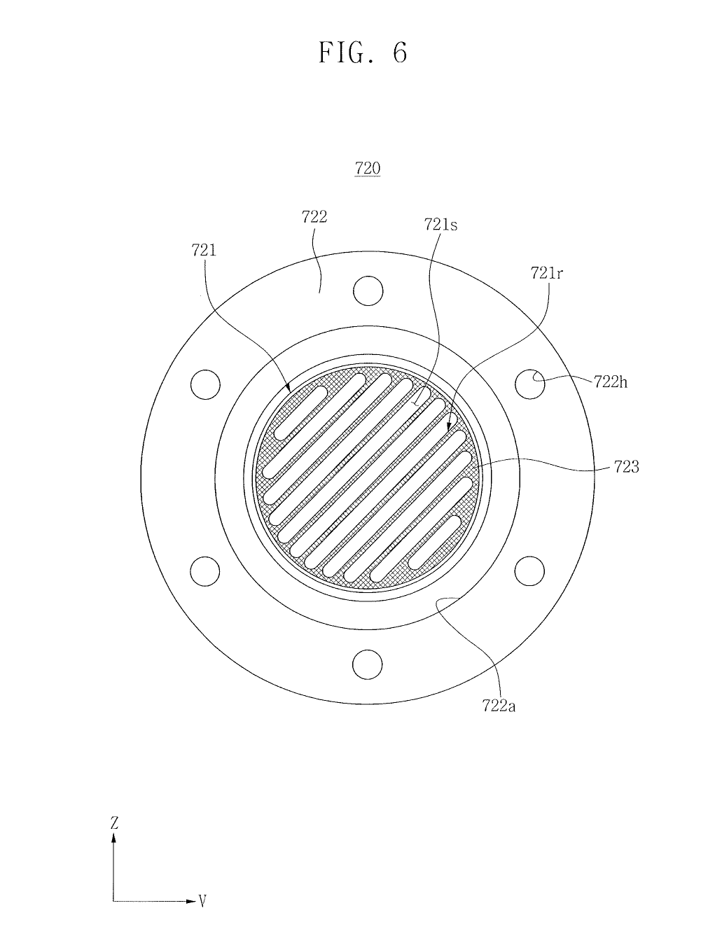

In addition, in the plasma process apparatus in accordance with the embodiment, it is described that the openings 721s and the guide ribs 721r of the light guide 720 extend in the Y-axis direction. However, in the plasma process apparatus in accordance with the embodiment, the openings 721s and the guide ribs 721r of the light guide 720 may extend in a Z-axis direction as shown in FIG. 5. Here, the Z-axis direction may be a direction perpendicular to the surface of the process chuck 120 shown in FIG. 1. Alternatively, in the plasma process apparatus in accordance with the embodiment, the openings 721s and the guide ribs 721r of the light guide 720 may extend in a direction diagonal to the Y-axis direction with a predetermined slope as shown in FIG. 6.

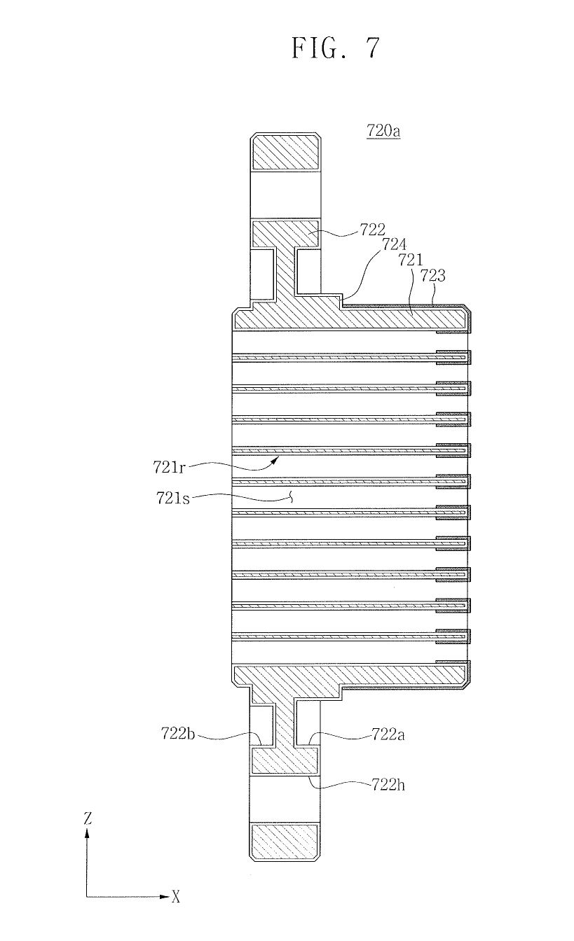

FIG. 7 is a cross-sectional view showing a light guide 720a of a plasma process apparatus in accordance with an embodiment.

Referring to FIG. 7, the light guide 720a of the plasma process apparatus in accordance with the embodiment may include the guide body 721, the guide flange 722, the guide coating layer 723, and further a guide oxidized layer 724. Openings 721s and guide ribs 721r may be located in the guide body 721. The guide flange 722 may include the inner flange groove 722a, the outer flange groove 722b, and the flange coupling hole 722h.

The guide oxidized layer 724 may be formed on, e.g., directly on, a surface of the guide body 721. The guide oxidized layer 724 may be formed on, e.g., directly on, a surface of the guide flange 722. The guide oxidized layer 724 may be formed on surfaces of the guide ribs 721r. The guide oxidized layer 724 may be formed between the guide body 721 and the guide coating layer 723. The guide coating layer 723 may be located on the guide oxidized layer 724.

The guide oxidized layer 724 may include the same material as the guide body 721. The guide oxidized layer 724 may include the same material as the guide flange 722. For example, the guide oxidized layer 724 may include aluminum oxide (Al₂O₃). For example, the guide oxidized layer 724 may be formed by an anodizing process.

In the plasma process apparatus in accordance with the embodiment, the guide oxidized layer 724 may be formed on a surface of the light guide 720a. Thus, in the plasma process apparatus in accordance with the embodiment, a state of plasma and an ongoing state of a designed process using plasma may be accurately monitored without damage to the light guide 720a due to plasma.

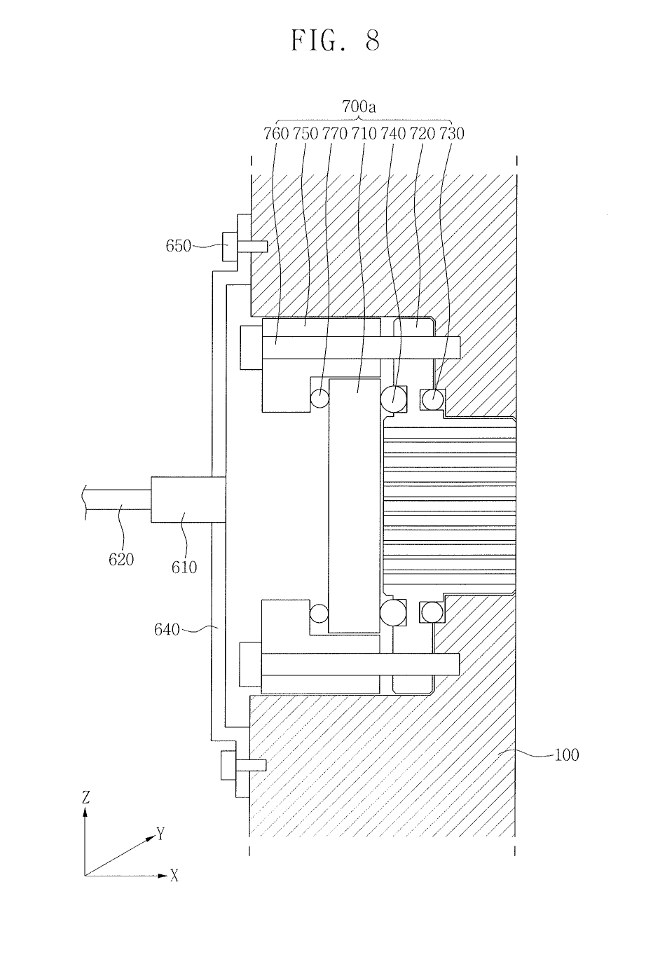

FIG. 8 is a cross-sectional view showing a light transmission element 700a of a plasma process apparatus in accordance with an embodiment.

Referring to FIG. 8, the light transmission element 700a of the plasma process apparatus in accordance with the embodiment may include the window plate 710, the light guide 720, the inner sealing element 730, the outer sealing element 740, the window fixing frame 750, the frame coupling element 760, and the buffer element 770.

The light guide 720 may be spaced, e.g., completely spaced, apart from the window plate 710, e.g., so the light guide 720 may not contact the window plate 710. The inner sealing element 730 may be in direct contact with the window plate 710 and the light guide 720. A space between the window plate 710 and the light guide 720 may be surrounded by the outer sealing element 740.

In the plasma process apparatus in accordance with the current embodiment, damage to the window plate 710 may be prevented while the light transmission element 700 is coupled to the process chamber 100. Thus, in the plasma process apparatus in accordance with the current embodiment, a state of plasma and an ongoing state of a designed process using plasma may be accurately monitored without damage to the window plate 710.

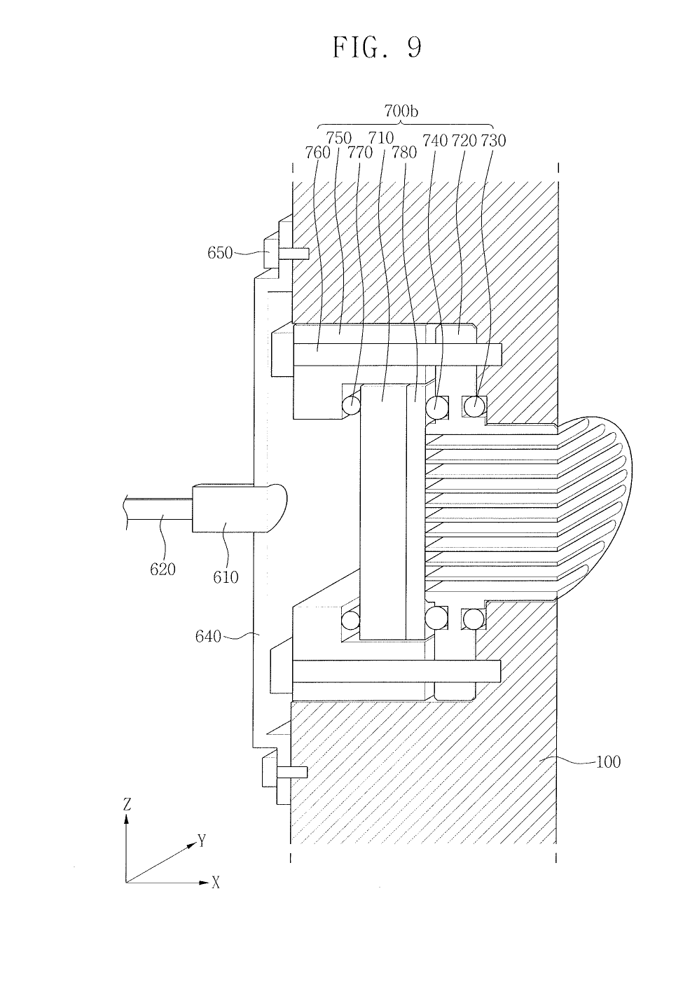

FIG. 9 is a view showing a light transmission element 700b of a plasma process apparatus in accordance with an embodiment.

Referring to FIG. 9, the light transmission element 700b of the plasma process apparatus in accordance with the embodiment may include the window plate 710, the light guide 720, the inner sealing element 730, the outer sealing element 740, the window fixing frame 750, the frame coupling element 760, the buffer element 770, and further a cover plate 780.

The cover plate 780 may prevent damage of the surface 710a of the window plate 710 exposed by the light guide 720 by plasma generated inside the process chamber 100. The cover plate 780 may be located between the window plate 710 and the light guide 720. The cover plate 780 may be in direct contact with the window plate 710. The cover plate 780 may directly contact a region of the light guide 720.

The outer sealing element 740 may be located between the light guide 720 and the cover plate 780. The outer sealing element 740 may be in direct contact with the cover plate 780.

Plasma resistance of the cover plate 780 may be greater than plasma resistance of the window plate 710. For example, the cover plate 780 may include sapphire.

Transmittance through the cover plate 780 may be lower than transmittance through the window plate 710. A thickness of the cover plate 780 may be smaller than a thickness of the window plate 710 along the X-axis direction.

In the plasma process apparatus in accordance with the embodiment, the cover plate 780 may be located between the window plate 710 and the light guide 720. Thus, in the plasma process apparatus in accordance with the embodiment, damage of the window plate 710 due to plasma may be prevented by the cover plate 780. Therefore, in the plasma process apparatus in accordance with the embodiment, a state of plasma and an ongoing state of a designed process may be accurately monitored using light generated by plasma generated inside the process chamber 100.

By way of summation and review, light generated by plasma in a plasma process apparatus may be applied to an analysis unit through a light transmission element located in a view port of a process chamber. However, process by-products generated by the plasma may be deposited on a surface of a window plate of the light transmission element, thereby clogging the window plate and minimizing light transmission therethrough.

In contrast, according to the plasma process apparatus in the exemplary embodiments, a light transmission element located in a view port of a process chamber includes a window plate and a light guide which prevents progressive clogging of the window plate. Accordingly, in the plasma process apparatus in accordance with the embodiments, light applied to the analysis unit through the light guide and through the window plate can be sufficiently ensured from a beginning of a designed process. Therefore, in the plasma process apparatus in accordance with the embodiments, a state of plasma generated inside the process chamber and an ongoing state of a designed process can be accurately monitored.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A plasma process apparatus, comprising:
a process chamber including a view port;
a window plate disposed in the view port of the process chamber; and
a light guide disposed on a surface of the window plate facing toward an interior of the process chamber, the light guide including openings extending in one direction in parallel to each other.

2. The plasma process apparatus as claimed in claim 1, further comprising a guide coating layer on a surface of the light guide facing toward the interior of the process chamber.

3. The plasma process apparatus as claimed in claim 2, wherein the guide coating layer includes yttria (Y₂O₃).

4. The plasma process apparatus as claimed in claim 2, wherein the guide coating layer extends along inner walls of the openings.

5. The plasma process apparatus as claimed in claim 1, further comprising a sealing element disposed between the window plate and the light guide, the sealing element surrounding the openings.

6. The plasma process apparatus as claimed in claim 5, wherein the light guide further comprises a flange groove accommodating the sealing element.

7. A plasma process apparatus, comprising:
a process chamber including:
a process chuck to support a process object, and
a view port to transmit light generated by plasma;
a light transmission element disposed in the view port of the process chamber; and
an analysis unit to analyze light transmitted through the light transmission element in the view port,
wherein the light transmission element includes a light guide having guide ribs extending in one direction, and a window plate disposed on surfaces of the guide ribs facing toward the analysis unit.

8. The plasma process apparatus as claimed in claim 7, wherein the guide ribs extend in a direction parallel with a surface of the process chuck.

9. The plasma process apparatus as claimed in claim 7, wherein the light guide further comprises a guide coating layer covering end portions of the guide ribs facing toward an interior of the process chamber.

10. The plasma process apparatus as claimed in claim 9, wherein the light guide further comprises a guide oxidized layer on a surface thereof, the guide coating layer being disposed on the guide oxidized layer.

11. The plasma process apparatus as claimed in claim 7, wherein a width of each of the guide ribs is constant.

12. The plasma process apparatus as claimed in claim 7, wherein a distance between adjacent guide ribs is greater than a width of each guide rib.

13. The plasma process apparatus as claimed in claim 7, wherein the light guide further comprises a guide flange disposed outside of the guide ribs, a distance between the window plate and the guide flange being greater than a distance between the guide ribs and the window plate.

14. The plasma process apparatus as claimed in claim 13, wherein the guide ribs are in direct contact with the window plate.

15. The plasma process apparatus as claimed in claim 7, wherein the analysis unit includes an optic emission spectrometer (OES).

16. A plasma process apparatus, comprising:
a process chamber including a view port;
a light guide disposed in the view port of the process chamber, the light guide including a guide body having a plurality of slits and a guide flange disposed outside of the guide body;
a window plate disposed on a surface of the guide body facing toward an exterior of the process chamber; and
an analysis unit to analyze light transmitted through the plurality of slits and the window plate.

17. The plasma process apparatus as claimed in claim 16, wherein opposite surfaces of the guide flange are disposed between opposite surfaces of the guide body.

18. The plasma process apparatus as claimed in claim 17, wherein the light guide further comprises a guide coating layer disposed on a surface of the guide body protruding from the guide flange in a direction facing toward an interior of the process chamber.

19. The plasma process apparatus as claimed in claim 16, further comprising a cover plate disposed between the window plate and the light guide, plasma resistance of the cover plate being greater than plasma resistance of the window plate.

20. The plasma process apparatus as claimed in claim 19, wherein a thickness of the cover plate is smaller than a thickness of the window plate.

21-25. (canceled)
